(19) United States
(12) Patent Application Publication
(10) Pub. No.: US 2004/0188777 A1
(43) Pub. Date: Sep. 30, 2004

(54) Mixed signal embedded mask ROM with virtual ground array and method for manufacturing same

(75) Inventor: Chong Jen Hwang, Sanchung City (TW)

Correspondence Address: HAYNES BEFFEL & WOLFELD LLP, P O BOX 366, HALF MOON BAY, CA, 94019, US

(73) Assignee: MACRONIX INTERNATIONAL CO., LTD., Hsinchu (TW)

(21) Appl. No.: 10/403,345

(22) Filed: Mar. 31, 2003

(51) Int. Cl. H01L 29/788

(52) U.S. Cl. 257/403

(57) ABSTRACT

A mixed signal integrated circuit including an embedded ROM array is manufactured using a two polysilicon process, with small critical dimensions. A first layer of polysilicon covered with a dielectric, adapted for formation of transistor gates and capacitor bottom electrodes, is formed in a non-array portion of the substrate. A second layer of polysilicon, adapted for formation of word lines in the array portion of the substrate, and capacitor top electrodes, is formed over the dielectric layer. The second layer of polysilicon is patterned to define word lines in the array portion and the capacitor top electrodes. Next, the array portion and the capacitor top electrodes are protected, and the first layer of polysilicon is patterned, to define transistor gates and the capacitor bottom electrodes. Salicide processing is applied to the non-array portion of the integrated circuit.

### BACKGROUND OF THE INVENTION

1. Field of the Invention

The present invention relates to integrated circuit devices for advanced mixed signal applications, and to methods for manufacturing the same; and more particularly to mixed signal integrated circuits with embedded memory arrays.

2. Description of Related Art

Many applications of integrated circuit technology have developed in which both analog and digital circuit elements are included on a single chip. For example, mixed signal devices having a combination of memory arrays, logic circuits and capacitors have been developed. In Lai et al., U.S. Pat. No. 6,440,798 B1, a mixed-signal circuit with a combination of embedded mask ROM, embedded NROM and capacitors is described.

As device dimensions on integrated circuits shrink, the design of such mixed signal integrated circuits becomes more complicated. For example, in small dimension transistors, it is desirable to apply a self-aligned silicide (known as “Salicide”) process to form conductive silicides on the surface of source and drain regions of peripheral circuitry for improved conductivity. However, for devices having both memory arrays and circuitry supporting mixed signals that requires Salicide processing, a difficulty arises because of the need to protect the array portion of the integrated circuit from the Salicide process so that silicide is not formed in the spaces between the wordlines. Silicide in the wordline spaces can create leakage paths in flat ROM virtual ground arrays, for example. Thus, embedded ROM with mixed signal devices has been impractical for integrated circuits with, for example, 0.25 micron and below process dimensions.

It is desirable therefore to provide a mixed signal integrated circuit, and manufacturing process for a mixed signal integrated circuit, that includes a memory array, peripheral circuits, and capacitors on a single substrate with small process dimensions.

### SUMMARY OF THE INVENTION

The present invention provides an efficient manufacturing method for mixed signal devices, that also overcomes the “Salicide difficulty” of prior art embedded ROM mixed signal devices having small critical dimensions. The present invention also provides unique mixed signal devices with small critical dimension circuitry having Salicide processed transistors. The invention also enables such devices having critical dimensions of about 0.25 microns and below.

According to one embodiment of the invention, a mixed signal integrated circuit including an embedded ROM array is manufactured using a two polysilicon process. A first layer of polysilicon, adapted for formation of transistor gates and capacitor bottom electrodes, is formed in a non-array portion of the integrated circuit substrate. The first layer of polysilicon is covered with a dielectric, at least in the capacitor regions. A second layer of polysilicon, adapted for formation of word lines in the array portion of the integrated circuit substrate, and capacitor top electrodes over the capacitor bottom electrodes, is formed over the dielectric layer. The second layer of polysilicon is patterned to define word lines in the array portion and the capacitor top electrodes. Next, the array portion and the capacitor top electrodes are protected, and the first layer of polysilicon is patterned, to define transistor gates and the outside dimensions of the capacitor bottom electrodes. According to this process flow, Salicide processing may be applied to the non-array portion of the integrated circuit substrate while blocking formation of silicides in the word lines spaces of the array portion of the integrated circuit.

Another embodiment of the invention is a mixed signal integrated circuit, including a read-only memory array, a polysilicon-insulator-polysilicon capacitor, and peripheral circuits having silicide on the source and drain regions of the substrate. Further embodiments of the invention comprise peripheral circuits and memory cells with critical dimensions defined by lithography processes of 0.25 microns and less.

According to one specific embodiment of the present invention, a method for manufacturing is provided which comprises:

forming a shallow trench isolation structure on the substrate;

forming a gate oxide layer in a non-array portion of the substrate;

covering the non-array portion and the isolation structure with a first layer of polysilicon;

covering the first layer of polysilicon in the non-array portion and in a first capacitor plate region over the isolation structure with a capacitor dielectric layer;

patterning bit lines in the array portion;

implanting dopants into the substrate between the bit line patterns;

removing said bit line patterns;

forming gate oxide in the array portion;

covering the remaining portions of said first layer of polysilicon and said capacitor dielectric layer, and covering the array portion with a second layer of polysilicon material and silicide;

patterning word lines in the array portion and top capacitor plate over the first capacitor plate region, and etching the second layer of polysilicon and silicide to form wordlines in the array portion, and a top capacitor plate structure over the first capacitor plate region;

patterning said first layer of polysilicon and said layer of capacitor dielectric to define transistor gates in the non-array portion, and a bottom capacitor plate in the bottom capacitor plate region;

forming self aligned silicide in source and drain regions in the non-array portion;

implanting ROM codes in the array portion;

implanting a first dopant aligned with the transistor gate structures in the non-array portion;

forming sidewall spacers with silicon nitride on the transistor gate structures, and between the wordlines in the array portion; and

implanting a second dopant in the non-array portion aligned with the sidewall spacers;

applying a dielectric layer over the array portion and the non-array portion; and

applying patterned metallization over the dielectric layer.

Accordingly, the present invention overcomes the “Salicide difficulty” encountered in prior art processes for manufacturing mixed signal devices with embedded ROM. In particular, the array portion of the substrate is protected from the Salicide process using simple array blocking and a straightforward process flow. Thus, unique integrated circuit embodiments of the invention are provided comprising small dimension mixed signal designs with embedded ROM.

Other aspects and advantages of the present invention can be seen on review of the drawings, the detailed description and the claims, which follow.

### BRIEF DESCRIPTION OF THE DRAWINGS

FIGS. 1A and 1B are a flow chart of a manufacturing process according to one embodiment of the present invention.

FIGS. 2-9 illustrate structures at various steps in an embodiment of the manufacturing process for a mixed signal integrated circuit including an embedded mask ROM.

### DETAILED DESCRIPTION

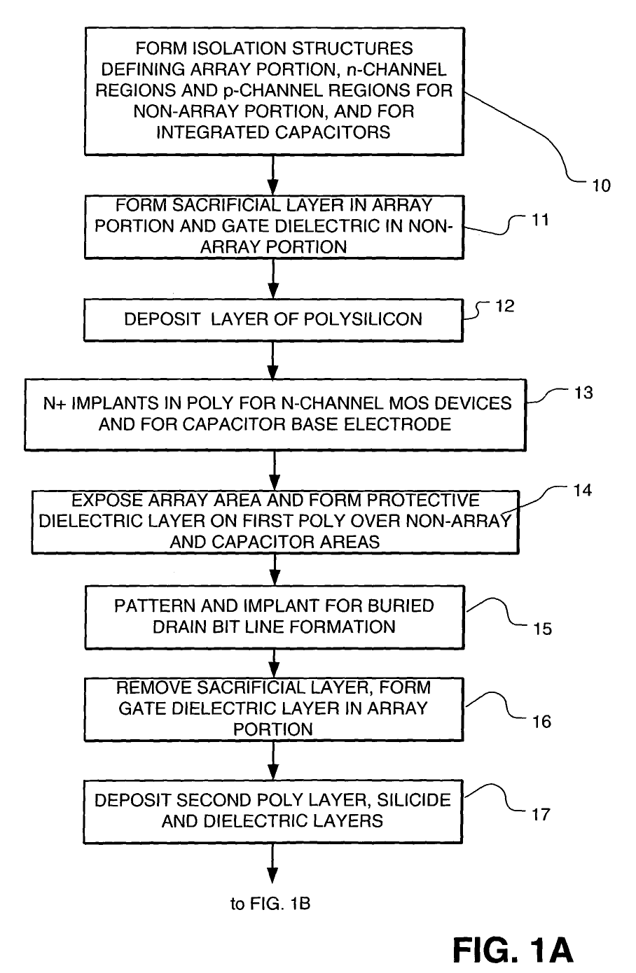

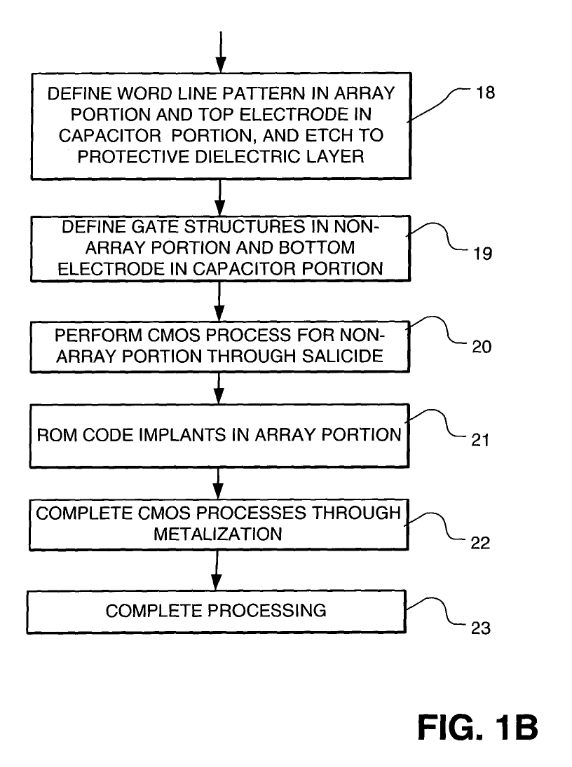

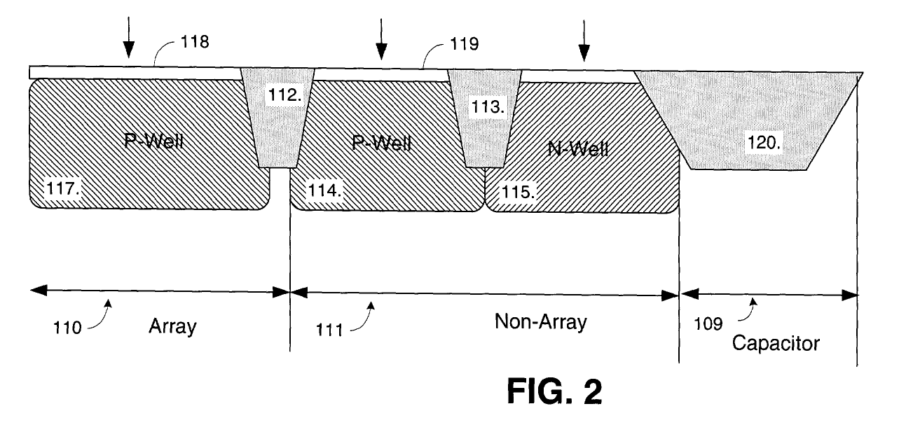

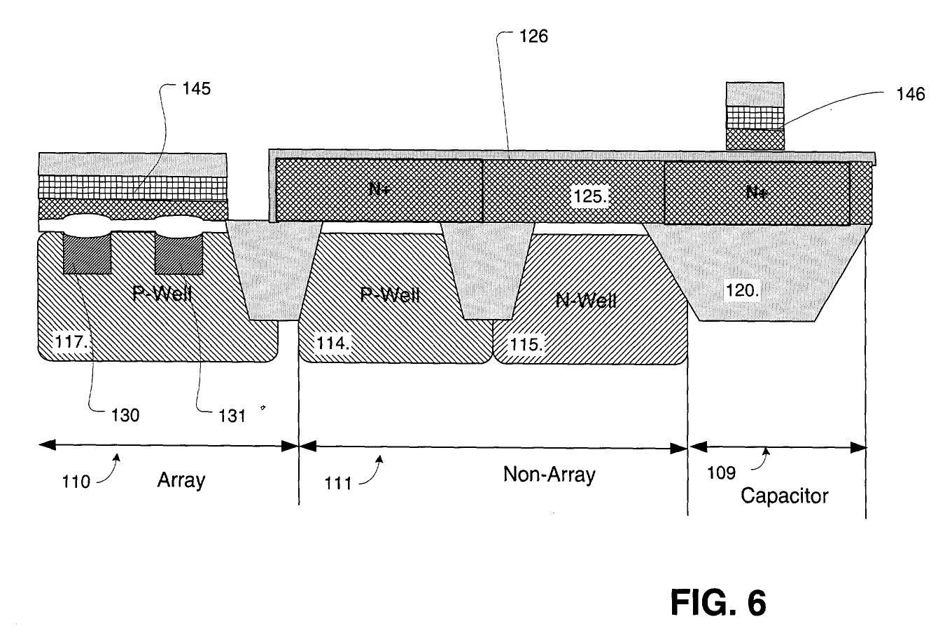

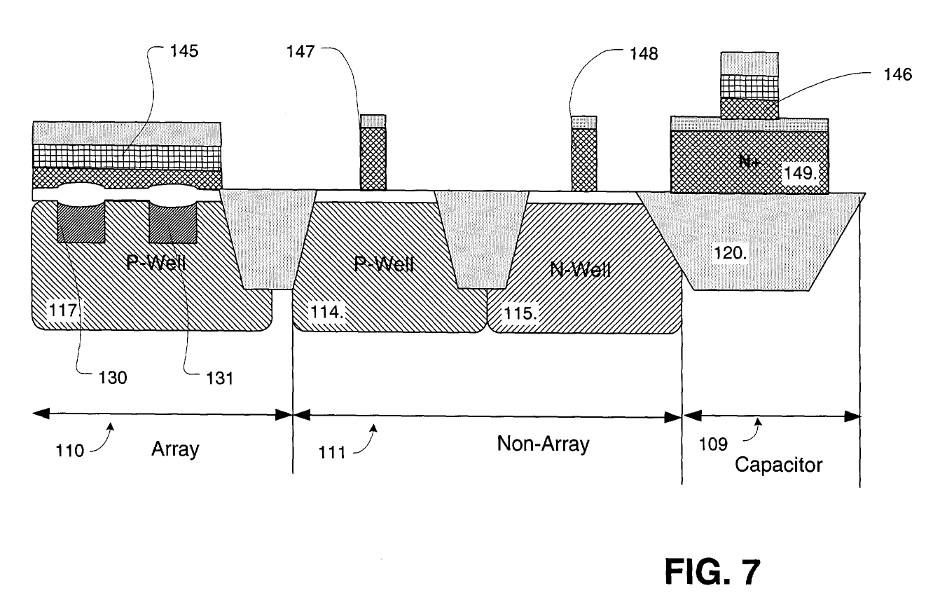

A detailed description of embodiments of the present invention is provided with reference to the figures, in which FIGS. 1A and 1B illustrate a basic flow for a representative manufacturing process. The structures at various steps in the manufacturing process are shown in FIGS. 2-9 for mask ROM based embedded memory devices for mixed signal applications.

A first step in the manufacturing process is to form isolation structures that define an array portion 110 and a non-array portion 111 of the substrate (block 10). FIG. 2 provides a view of a resulting structure. In the example shown in FIG. 2, the array portion 110 is isolated from the non-array portion by dielectric isolation structure 112. The non-array portion 111 is divided into an n-channel region and a p-channel region by dielectric isolation structure 113 for typical CMOS implementation of logic circuits. In addition, in this embodiment an isolation structure 120 is formed in a capacitor region on the non-array portion of the substrate. The dielectric structures 124, 113 and 120 are formed by depositing oxide or other dielectric within a trench, by LOCOS oxidation, or otherwise as known in the art. In a preferred embodiment, shallow trench isolation structures are formed, such as described in Huang et al., U.S. Pat. No. 6,191,000 B1, entitled SHALLOW TRENCH ISOLATION MEHTOD USED IN A SEMICONDUCTOR WAFER. The isolation structure 120 has a flat surface in the illustrated embodiment, on which a bottom electrode of a capacitor may be formed as described below. Alternatively, the surface of the isolation structure 120 may be shaped, for example to increase a surface area of a capacitor electrode formed thereon.

The n-channel region is defined by p-type well 114 in which n-channel devices are formed. The p-channel region is defined by the n-type well 115 in which p-channel devices are formed. In this example, the array portion 110 includes a deep n-type well 116, in which a p-type well 117 is formed. N-channel memory devices are formed in the p-type well 117. In one example process, a retrograde well formation process is used to create the deep well structure and to apply Vt implants in the memory cell region. The process includes two retrograde well processes including a well implant→anti-punch through implant→and Vt implant using the same mask. Two masking layers are then used in this example to form the n-type well 116 and the p-type well 117 according to the retrograde well approach. For the NMOS devices, representative implant recipes include a Vt implant using BF2 with 50K˜80K KeV, with a concentration of about 1E12 dose/cm\hat{ }2, an anti-punch implant using B with 50K˜80K KeV, with a concentration of about 1E12 dose/cm\hat{ }2, and a well implant using B with 150K˜250K KeV, with a concentration of about 1E13 dose/cm\hat{ }2. For the PMOS devices, representative implant recipes include a Vt implant using P at 100˜120K KeV, with a concentration of about 2E12 dose/cm\hat{ }2, an anti-punch implant using P at 250K˜300K KeV, with a concentration of about 2E12 dose/cm\hat{ }2, and a well implant using P at 550K˜600K KeV, with a concentration of about 1E13 dose/cm\hat{ }2. This combination of well structures in the array portion 110 is used for isolation purposes in some embodiments.

In a next step (block 11) of FIG. 1A, a sacrificial dielectric layer 118 is formed in the array portion and a peripheral gate dielectric layer 119 is formed in the non-array portion as shown in FIG. 2. The sacrificial dielectric layer 118 in the array portion may be formed in the same process step as the peripheral gate dielectric layer 119 formed in the non-array portion, or different processes may be used so as to establish different parameters for the dielectrics in the various regions. Also, the peripheral gate dielectric layer 119 may have varying characteristics in different areas, to accommodate a variety of mixed signal integrated circuit components.

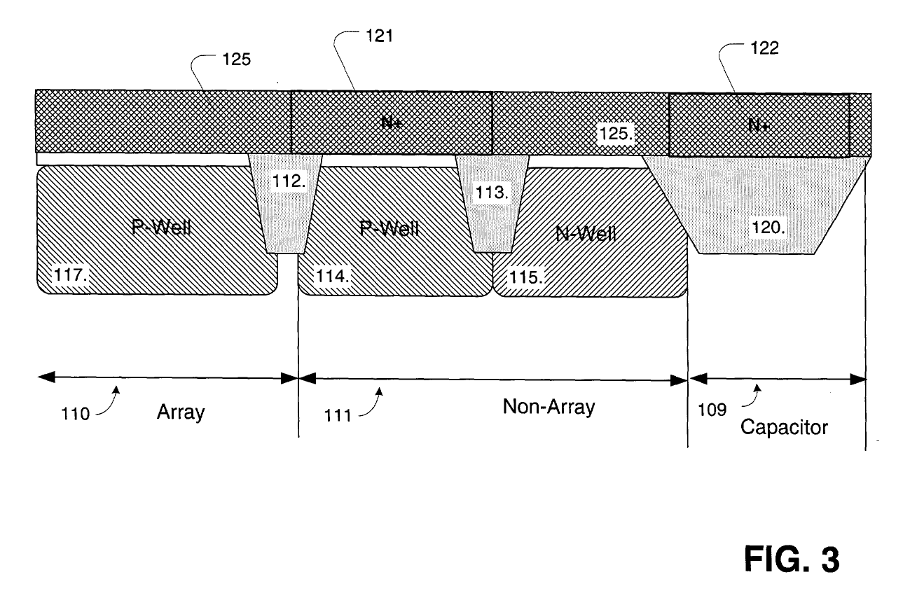

Next, a first layer of polysilicon 125 is deposited over the sacrificial dielectric layer 118 and peripheral gate dielectric layer 119 (block 12). The first layer of polysilicon 125 is doped using implants for n-channel MOS devices in region 121 and for the capacitor bottom electrode in region 122 in the non-array portion, as shown in FIG. 3 (block 13).

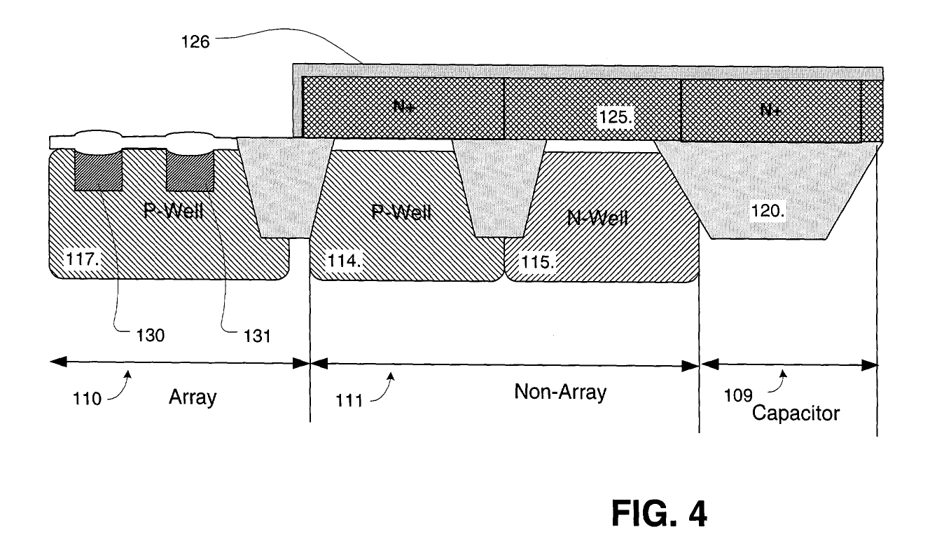

After preparation of the first layer of polysilicon 125, the array area is exposed by masking and etching away the first layer of polysilicon in the array portion, leaving the first layer of polysilicon 125 over the non-array portion of the substrate, including the capacitor region. A protective dielectric layer 126 is formed as shown in FIG. 4 on the remaining portions of the first layer of polysilicon 125, including on the sidewalls of the first layer of polysilicon around the perimeter of the array portion of the substrate (block 14). In one embodiment, the protective dielectric layer 126 comprises a thermal oxide have a thickness of about 300 angstroms. Other materials may be uetilized as well, which may act both as a protective layer, and as a capacitor dielectric layer. The combination of the remaining portions of the first layer of polysilicon 125 with the protective dielectric layer 126 act as a mask during steps used for definition of the memory array.

In a next step, buried diffusion bitlines are formed by a photolithographic patterning process, followed by an ion implantation and photoresist stripping. In one embodiment, the bitlines defined have widths defined by the critical manufacturing dimension of the lithographic process. In some embodiments, the widths are 0.25 microns or less. The resulting bit lines comprise parallel diffusion lines 130,131 as shown in FIG. 4, extending into the page of the drawing (block 15). One example recipe for the buried diffusion BD implant includes a “pocket” p-type implant of boron B with an implant energy of 15˜40K KeV, and concentration of 1˜5E13 atom/cm\hat{ }2, after an n-type BD implant of arsenic As with an implant energy of 30˜60K KeV, and a concentration of 2˜3.5E15 atom/cm\hat{ }2. Of course, as with all implant processes, these energies and concentrations are fine tuned according to the structures and processes of the particular chip and particular fab. Next, the sacrificial dielectric layer is removed in the array portion, and a gate dielectric layer 135 is formed for the array along with isolation oxide 136 for the buried diffusion bit lines (Block 16).

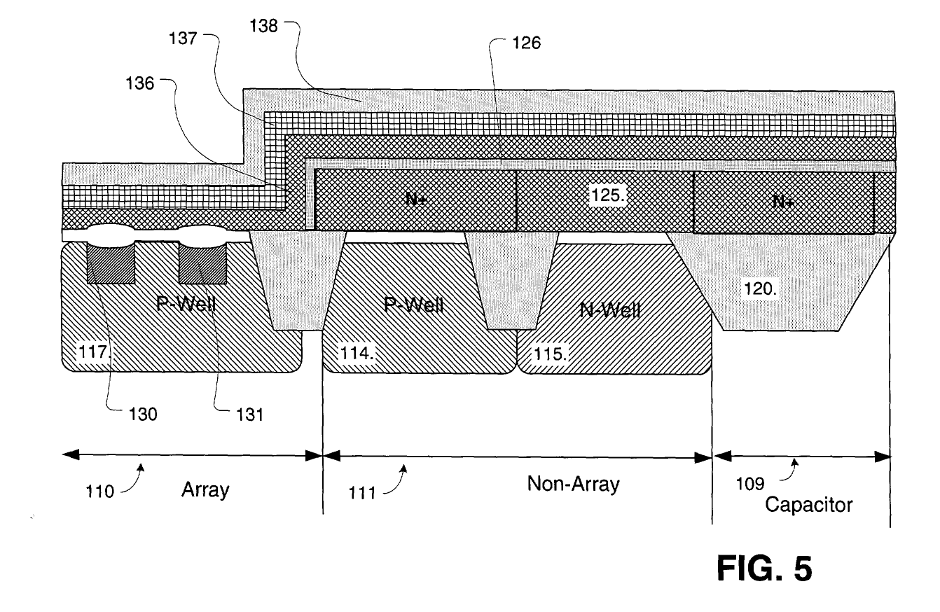

After preparation of the bit lines 130, 131 and gate dialectic 135 for the array, a second layer of polysilicon 136 is deposited over the substrate, including over the first layer of polysilicon 125 and protective dielectric 126 as shown in FIG. 5. In one embodiment, the second layer of polysilicon 136 is deposited using a chemical vapor deposition process. In a preferred embodiment, a layer of tungsten silicide 137 is deposited over the second layer of polysilicon 136. A layer of oxide 138 is deposited using a CVD process over the silicide 137 having a thickness of around 300 to 500 angstroms (Block 17). This composite second layer of polysilicon 136 with silicide 137 is used for definition of word lines in the array portion and a top electrode on the capacitor in the capacitor region as described below.

Thus in a next step, the word lines 145 and capacitor top electrode 146 are defined using photolithographic processes, and the composite second layer of polysilicon 136 and silicide 137 are etched down to the protective dielectric layer of 126 (block 18). The widths of the word lines 145 may be defined by the critical manufacturing dimension of the lithographic process. In some embodiments, the widths are 0.25 microns or less. For the next step, gate structures 147,148 in the non-array portion and the bottom electrode 149 in the capacitor portion are defined using a photolithographic process, which also protects the array portion. The defined pattern is etched down to the gate dielectric layer 119 in the non-array portion (block 19). The widths of the gate structures for one or more transistors in the peripheral circuits are defined by the critical manufacturing dimension of the lithographic process. In some embodiments, the widths are 0.25 microns or less. Next, the photoresist is removed, and CMOS processes are followed in the non-array portion, including self aligned silicide processes.

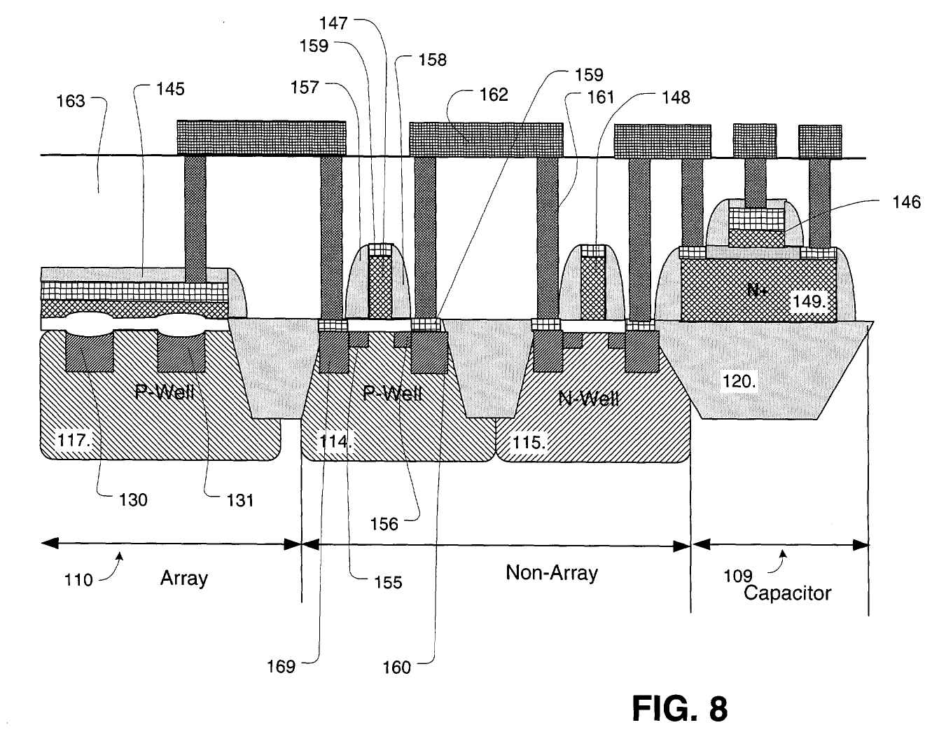

Representative CMOS processes include a re-oxidation step followed by lightly doped drain LDD processes, beginning with a first implantation step in the non-array portion, aligned with the gate structures 147, 148. The structure can be seen in FIG. 8, which shows a cross-section parallel with the wordline 145. This first implantation results in a diffusion region 155 and a diffusion region 156 closely aligned with the sides of the gate structure 147. Next, silicon nitride sidewall spacers 157, 158 are formed, by depositing a layer of silicon nitride, and then anisotropically etching the silicon nitride down to the underlying structures. One example SiN deposition recipe includes N2/NH3/SiH2C12 mixed-chemical chemical vapor deposition with a chamber wall temperature of 730 C. The silicon nitride is etched in one example process using a dry etch (e.g. 75 mt/1600 W/C4F8/Ar/CH3F) where mt means milli-torr and W is watts, mixed-chemical with endpoint set to stop etch process on the SiO2 gate dielectric layer. As seen in FIG. 8, this etch step results in sidewall spacers, e.g. 157, 158, on the structures on the substrate (block 20). The LDD processes in the non-array portion are completed by a second implantation step, aligned with the sidewall spacers 157, 158. As seen in FIG. 8, this results in the diffusion regions 169, 160 aligned with the sidewall spacers 157, 158 and spaced away from the sides of the gate structure 147, while overlapping with the diffusion regions 155 and 156. The spacers 157, 158 are formed using silicon nitride in this embodiment to improve selectivity of the etch back step used for sidewall formation with the underlying dielectric on the surface of the substrate, and with the CVD dielectric in the array portion of the substrate. Other materials may be used for the sidewall spacers, which support select etching relative to the gate dielectric material.

In a next step, the self aligned silicide (Salicide) process is applied. As seen in FIG. 8, the Salicide process forms conductive silicide 159 over the exposed diffusion regions in alignment with the sidewall spacers 157, 158, and on top of the gate structures in the non-array portion. The diffusion bit lines in the array portion of the device are protected from Salicide process by the array masking during the silicide steps in one embodiment. For example, during the etch-back step of the silicide process, the array portion is protected by a mask preventing sidewall formation in the array portion while leaving a layer of silicon nitride to block silicide formation between the word lines. Alternatively, the silicon nitride deposition for sidewall formation results in sidewalls which in combination fill between the wordlines, and protect the wordline spaces from the Salicide process. In yet another embodiment, CVD oxide is deposited between the wordlines, prior to patterning the first polysilicon layer, and protects against damage to the array portion during the CMOS processes in the non-array portion.

After the Salicide process, ROM code implants are made in the array portion of the device using a cycle including photoresist mask, implant, and photoresist strip steps (block 21).

Finally, a dielectric layer 163, contact vias 161 and patterned metallization 162 are applied to complete the device (block 22). Final device processing is carried out to produce a complete bonding and packaging for a mixed signal integrated circuit with embedded flat ROM (block 23).

FIG. 8 shows a cross-section of a integrated circuit substrate having a mask ROM in the array portion 110 arranged in a flat, virtual ground architecture, combined with peripheral circuits in the non-array portion 111 including digital and analog transistors implemented using CMOS processes.

Also, a polysilicon-insulator-polysilicon (PIP) capacitor is formed over the isolation structure 120. The isolation structure 120 acts to prevent formation at a parasitic capacitor with the substrate. The PIP capacitor includes a bottom electrode 149 formed using the first polysilicon, and a top electrode 146 formed using the second polysilicon. The top electrode 146 is around four microns square in one example process, so that a capacitance value useful in typical mixed signal applications can be implemented. Of course, smaller and greater sizes can be implemented, as suits a particular mixed signal application. In addition, the edge of the bottom electrode 149 is preferably spaced around 1 micron away from the edge of the active area along the sides of the isolation structure 120.

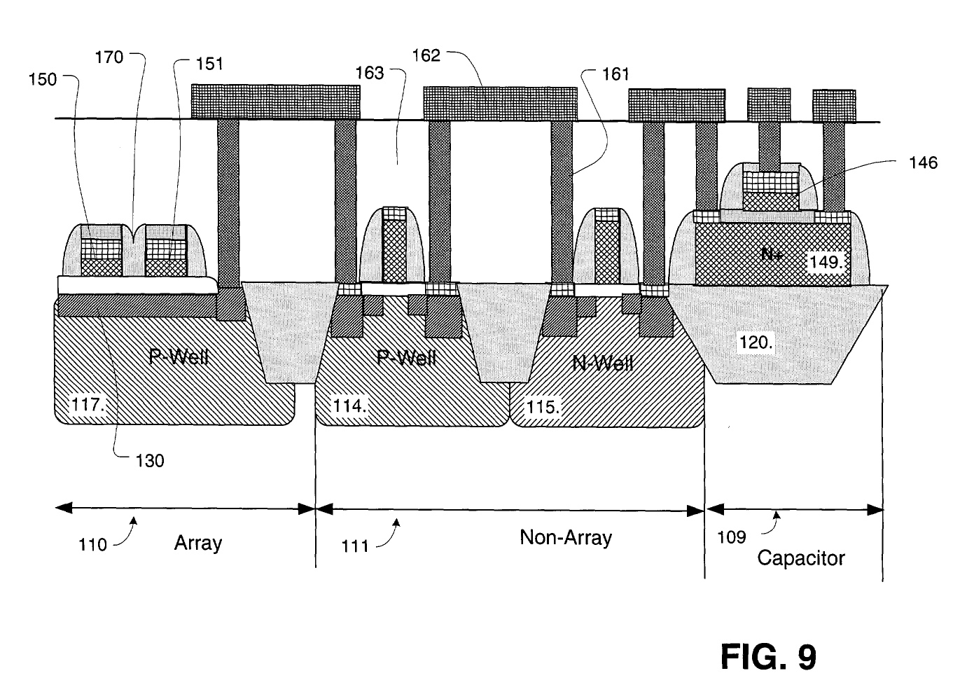

FIG. 9 illustrates the integrated circuit in the stage of manufacturing shown in FIG. 8, in cross section parallel to the buried diffusion bit line 130. Word line structures 150 and 151 are disposed orthogonally relative to the bit lines. In this embodiment, spaces 170 between the wordlines are filled with silicon nitride from the silicon nitride side wall process described above, protecting the dielectric layer 136 from silicide formation during the Salicide process.

As integrated circuit manufacturing processes shrink beyond 0.25 microns, the deposition of silicides on source and drain regions and on gate electrodes in the peripheral circuitry becomes more critical for improved conductivity. However, prior art approaches have been incompatible with the Salicide process, which is the best-known technique for forming such a silicides. The present invention overcomes the Salicide difficulty, and enables true mixed signal devices with small dimension components.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A method for manufacturing an integrated circuit on a substrate, including a mask ROM in an array portion of the substrate and other circuitry including a capacitor in a non-array portion of the substrate, comprising:
covering the non-array portion with a first layer of polysilicon;
covering the first layer of polysilicon in at least a first capacitor plate region with a capacitor dielectric layer;
forming bit lines and a gate dielectric layer in the substrate in the array portion;
covering said first layer of polysilicon and said capacitor dielectric layer in the non-array portion, and covering the array portion with a second layer of polysilicon material;
forming word lines in the array portion and a top capacitor plate over the first capacitor plate region from the second layer of polysilicon;
forming transistor gates and a bottom capacitor plate in the bottom capacitor plate region from the first layer of polysilicon in the non-array portion;
implanting dopants to form source and drain regions in the non-array portion; and
applying a dielectric layer over the array portion and the non-array portion; and applying patterned metallization over the dielectric layer.

2. The method of claim 1, including
forming silicide in source and drain regions on the substrate in the non-array portion, while blocking silicide formation on the substrate in the array portion.

3. The method of claim 1, including
forming silicide on said wordlines in the array portion.

4. The method of claim 1, including implanting dopant in the first layer of polysilicon in gate regions in the non-array portion, and in the first capacitor plate region over the isolation structure.

5. The method of claim 1, including before said implanting dopants to form source and drain regions in the non-array portion, re-oxidizing the oxide layer in the non-array portion.

6. The method of claim 1, wherein said implanting dopants to form source and drain regions in the non-array portion includes:
implanting a first dopant aligned with the transistor gate structures;
forming sidewall spacers on the transistor gate structures; and
implanting a second dopant aligned with the sidewall spacers.

7. The method of claim 1, wherein said implanting dopants to form source and drain regions in the non-array portion includes:
implanting a first dopant aligned with the transistor gate structures;
forming sidewall spacers with silicon nitride on the transistor gate structures, and between the wordlines in the array portion; and
implanting a second dopant in the non-array portion aligned with the sidewall spacers.

8. The method of claim 1, including forming self aligned silicide in the non-array portion, and after forming self aligned silicide, implanting ROM codes in the array portion.

9. The method of claim 1, wherein said bit lines have a width of about 0.25 microns or less.

10. The method of claim 1, wherein at least one of said gate structures in the non-array portion has a width of about 0.25 microns or less, and including
forming silicide in source and drain regions on the substrate in the non-array portion, while blocking silicide formation on the substrate in the array portion.

11. A method for manufacturing an integrated circuit on a substrate, including a mask ROM in an array portion of the substrate and other circuitry including a capacitor in a non-array portion of the substrate, comprising:
forming an isolation structure on the substrate;
forming a gate oxide layer in the non-array portion of the substrate;
covering the non-array portion and the isolation structure with a first layer of polysilicon;
covering the first layer of polysilicon in the non-array portion and in a first capacitor plate region over the isolation structure with a capacitor dielectric layer;
patterning bit line patterns in a bit line direction in the array portion;
implanting dopants into the substrate between the bit line patterns;
removing said bit line patterns;
forming gate oxide in the array portion;
covering the remaining portions of said first layer of polysilicon and said capacitor dielectric layer, and covering the array portion with a second layer of polysilicon material;
patterning word lines in the array portion and a top capacitor plate over the first capacitor plate region, and etching the second layer of polysilicon to form wordlines in the array portion and a top capacitor plate structure over the first capacitor plate region;
patterning said first layer of polysilicon and said layer of capacitor dielectric to define transistor gates in the non-array portion, and a bottom capacitor plate in the bottom capacitor plate region;
implanting dopants to form source and drain regions in the non-array portion;
applying a dielectric layer over the array portion and the non-array portion; and
applying patterned metallization over the dielectric layer.

12. The method of claim 11, including
forming silicide in source and drain regions on the substrate in the non-array portion, while blocking silicide formation on the substrate in the array portion.

13. The method of claim 11, including
forming silicide on said wordlines in the array portion.

14. The method of claim 11, including implanting dopant in the first layer of polysilicon in gate regions in the non-array portion, and in the first capacitor plate region over the isolation structure.

15. The method of claim 11, including before said implanting dopants to form source and drain regions in the non-array portion, re-oxidizing the oxide layer in the non-array portion.

16. The method of claim 11, wherein said implanting dopants to form source and drain regions in the non-array portion includes:
implanting a first dopant aligned with the transistor gate structures;
forming sidewall spacers on the transistor gate structures; and
implanting a second dopant aligned with the sidewall spacers.

17. The method of claim 11, wherein said implanting dopants to form source and drain regions in the non-array portion includes:
implanting a first dopant aligned with the transistor gate structures;
forming sidewall spacers with silicon nitride on the transistor gate structures, and between the wordlines in the array portion; and
implanting a second dopant in the non-array portion aligned with the sidewall spacers.

18. The method of claim 11, including forming self aligned silicide in the non-array portion, and after forming self aligned silicide, implanting ROM codes in the array portion.

19. The method of claim 11, wherein said bit lines have a width of about 0.25 microns or less.

20. The method of claim 11, wherein at least one of said gate structures in the non-array portion has a width of about 0.25 microns or less, and including
forming silicide in source and drain regions on the substrate in the non-array portion, while blocking silicide formation on the substrate in the array portion.

21. A method for manufacturing an integrated circuit on a substrate, including a mask ROM in an array portion of the substrate and other circuitry including a capacitor in a non-array portion of the substrate, comprising:
forming a shallow trench isolation structure on the substrate;
forming a gate oxide layer in the non-array portion of the substrate;
covering the non-array portion and the isolation structure with a first layer of polysilicon;
covering the first layer of polysilicon in the non-array portion and in a first capacitor plate region over the isolation structure with a capacitor dielectric layer;
patterning bit line patterns in a bit line direction in the array portion;
implanting dopants into the substrate between the bit line patterns;
removing said bit line patterns;
forming gate oxide in the array portion;
covering the remaining portions of said first layer of polysilicon and said capacitor dielectric layer, and covering the array portion with a second layer of polysilicon material and silicide;
patterning word lines in the array portion and top capacitor plate over the first capacitor plate region, and etching the second layer of polysilicon and silicide to form wordlines in the array portion a top capacitor plate structure over the first capacitor plate region;
patterning said first layer of polysilicon and said layer of capacitor dielectric to define transistor gates in the non-array portion, and a bottom capacitor plate in the bottom capacitor plate region, wherein at least one of said transistor gates has a width of about 0.25 microns or less;
forming self aligned silicide in source and drain regions in the non-array portion;
implanting ROM codes in the array portion;
implanting a first dopant aligned with the transistor gate structures in the non-array portion;
forming sidewall spacers with silicon nitride on the transistor gate structures, and between the wordlines in the array portion; and
implanting a second dopant in the non-array portion aligned with the sidewall spacers;
applying a dielectric layer over the array portion and the non-array portion; and
applying patterned metallization over the dielectric layer.

22. The method of claim 21, including implanting dopant in the first layer of polysilicon in gate regions in the non-array portion, and in the first capacitor plate region over the isolation structure.

23. The method of claim 21, including before said implanting dopants to form source and drain regions in the non-array portion, re-oxidizing the oxide layer in the non-array portion.

24. An integrated circuit, comprising:
a semiconductor substrate;
an array of read-only memory cells on the semiconductor substrate;
peripheral circuits on the semiconductor substrate, coupled to the array, said peripheral circuits including transistors having source and drain regions in the semiconductor substrate and silicide on the source and drain regions; and
a capacitor on the semiconductor substrate.

25. The integrated circuit of claim 24, wherein the capacitor comprises a polysilicon-insulator-polysilicon device.

26. The integrated circuit of claim 24, wherein said array includes wordlines comprising polysilicon, and said capacitor includes a top plate comprising polysilicon and a bottom plate comprising polysilicon.

27. The integrated circuit of claim 24, wherein said peripheral circuits include transistors having transistor gates comprising first polysilicon, said array includes wordlines comprising second polysilicon, and said capacitor includes a top plate comprising the second polysilicon and a bottom plate comprising the first polysilicon.

28. The integrated circuit of claim 24, wherein said read only memory comprise mask ROM.

29. The integrated circuit of claim 24, including silicon nitride sidewall spacers on transistors in said peripheral circuits.

30. The integrated circuit of claim 24, wherein the capacitor comprises a polysilicon-insulator-polysilicon device over a shallow trench isolation structure.

31. The integrated circuit of claim 24, wherein said peripheral circuits include transistors having transistor gates, and at least one of said transistor gates has a width of about 0.25 microns or less.
